(19) United States
(12) Patent Application Publication
(10) Pub. No.: US 2005/0270083 A1
(43) Pub. Date: Dec. 8, 2005

(54) Radio frequency switching circuit and semiconductor device using the same

(75) Inventors: Tadayoshi Nakatsuka, Osaka (JP); Shigeru Kataoka, Kanagawa (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/134,351

(22) Filed: May 23, 2005

(30) Foreign Application Priority Data
Jun. 4, 2004 (JP) 2004-166976

(51) Int. Cl. H03F 3/217

(52) U.S. Cl. 327/430

(57) ABSTRACT

A radio frequency switching circuit includes a plurality of input/output terminals for inputting/outputting a radio frequency signal and a plurality of basic switching sections each being provided between adjacent two of the plurality of the input/output terminals. Each of the basic switching sections includes three or more field effect transistors connected in series. Each of two of the field effect transistors connected in series which are located in both ends of the basic switching section, respectively, has a higher threshold voltage than respective threshold voltages of other ones of the field effect transistors.

### CROSS-REFERENCE TO RELATED APPLICATION

The disclosure of Japanese Patent Application No. 2004-166976 filed on Jun. 4, 2004 including specification, drawings and claims are incorporated herein by reference in its entirety.

### BACKGROUND OF THE INVENTION

The present invention relates to a radio frequency switching circuit for switching radio frequency signals and a semiconductor device using the radio frequency switching circuit.

In recent years, expectations have been running high for a high-performance, radio frequency switch using a field effect transistor (FET) in the field of mobile communication system represented by cellular phones.

However, a radio frequency switch using a FET has a shortcoming. That is, a radio frequency characteristic of a radio frequency switch using a FET is deteriorated when a large power is input thereto.

To eliminate the shortcoming of a radio frequency switch using a FET, a technique in which a plurality of FETs are connected to one another in series has been conventionally proposed (see Japanese Laid-Open Publication No. 2002-232278).

Hereinafter, a radio frequency switching circuit according to a known example will be described with reference to FIG. 20.

FIG. 20 is a circuit diagram illustrating a circuit configuration of a known radio frequency switching circuit in which a plurality of FETs are connected in series. A radio frequency switching circuit shown in FIG. 20 has a configuration of a two-input/one-output called a “single-pole/double-throw (referred to as SPDT)” configuration. The radio frequency switching circuit includes three input/output terminals, i.e., a first input/output terminal 901, a second input/output terminal 902 and a third input/output terminal 903, a first basic switching section 801 and a second basic switching section 802. Each of the first and second basic switching sections 801 and 802 is provided between adjacent two of the input/output terminals.

The first basic switching section 801 includes four depletion-type-FETs. A source and a drain of a first FET 811, a source and a drain of a second FET 812, a source and a drain of a third FET 813 and a source and a drain of a fourth FET 814 are connected to one another in series in this order. The source of the first FET 811 is connected to the first input/output terminal 901. The drain of the fourth FET 814 is connected to the third input/output terminal 903. Moreover, a gate of each of the first through fourth FETs 811 through 814 is connected to a control terminal 911 via a resistance 851.

The second basic switching section 802 has a similar configuration to that of the first basic switching section 801. A source and a drain of a fifth FET 815, a source and a drain of a sixth FET 816, a source and a drain of a seventh FET 817 and a source and a drain of an eighth FET 818 are connected to one another in series in this order. The source of the fifth FET 811 is connected to the second input/output terminal 902. The drain of the eighth FET 818 is connected to the third input/output terminal 903. Moreover, a gate of each of the fifth through eighth FETs 815 through 818 is connected to a control terminal 912 via a resistance 851.

The first through fourth FETs 811 through 814 constituting the first basic switching section 801 and the fifth through eighth FETs 815 through 818 constituting the second basic switching section 802 have the same threshold, the same gate width and the same gate length.

Next, the operation of the known circuit will be described with reference to FIG. 20. When a radio frequency signal is input from the first input/output terminal 901 and output from the third input/output terminal 903, a voltage of 3 V is applied to the control terminal 911 and a voltage of 0 V is applied to a control terminal 912 to turn ON the first through fourth FETs 811 through 814 and turn OFF the fifth through eighth FETs 815 through 818. At this time, each of the respective potentials of drains and sources of the fifth through eighth FETs 814 through 818 is about 3 V and each of the respective gate voltages of the fifth through eighth FETs 815 through 818 is 0 V. Accordingly, a reverse bias voltage of −3 V is applied between the gate and source of each of the FETs.

In this case, floating capacitances C1, C3, C5 and C7 are present between the gate and source of the fifth FET 815, between the gate and source of the sixth FET 816, between the gate and source of the seventh FET 817 and between the gate and source of the eighth FET 818, respectively. Floating capacitances C2, C4, C6 and C8 are present between the gate and drain of the fifth FET 815, between the gate and drain of the sixth FET 816, between the gate and drain of the seventh FET 817 and between the gate and drain of the eighth FET 818, respectively. And floating capacitances C9, C10, C11 and C12 are present between the source and drain of the fifth FET 815, between the source and drain of the sixth FET 816, between the source and drain of the seventh FET 817 and between the source and drain of the eighth FET 818, respectively. In this known example, the fifth through eighth FETs 815 through 818 have the same gate width and the same gate length, and therefore, respective values of the floating capacitances C1 through C8 are the same. Also, respective values of the floating capacitances C9 through C12 are the same.

A radio frequency signal input from the radio frequency input terminal 901 is applied to the fifth through eighth FETs 815 through 818, each of which is in an OFF state, and the radio frequency signal voltage divided into eight by the floating capacitances C1 through C8 is superposed on each of the respective gates of the fifth through eighth FETs. Moreover, a voltage corresponding to the sum of a radio frequency signal voltage divided into four by the floating capacitances C9 through C12 and 3 V, i.e., a control voltage is applied between the drain and source of each of the fifth through eighth FETs 815 through 818.

To keep the fifth through eighth FETs 815 through 818 being in an OFF state, a voltage applied between the gate and drain of each of the fifth through eighth FETs 815 and 818 and a voltage applied between the gate and source of each of the fifth through eighth FETs 815 and 818 need to be lower than a threshold of each FET.

When a voltage between the gate and drain of any one of the fifth through eighth FETs 815 and 818 or a voltage between the gate and source of any one of the fifth through eighth FETs 815 and 818 is increased to a level almost over the threshold, a voltage between the gate and drain of an adjacent FET to the FET or a voltage between the gate and source the adjacent FET is increased, thereby compensating the increase in voltage between the gate and drain or the gate and source of any one of the fifth through eighth FETs 815 and 818. However, even when the fifth FET 815 becomes close to an ON state, the potential of source of the fifth FET 815 connected to the third input/output terminal 903 can not be increased. In the same manner, even when the eighth FET 818 becomes close to an ON state, the potential of drain of the eighth FET 818 can not be increased. Accordingly, the fifth FET 815 and the eighth FET 818 become in an ON state more easily, compared to the sixth FET 816 and the seventh FET 817.

When some of FETs constituting a basic switching section is turned ON, with this as a trigger, other FETs connected in series are also turned ON, so that the entire basic switching section is turned ON. Therefore, in order to keep a basic switching section being in an OFF state, it is important to keep an OFF state of FETs which are located in both ends, respectively, and are more easily turned ON, compared to a FET in the FETs in bothe ends.

When a FET that is normally to be in an OFF state is turned ON, a waveform of a radio frequency signal loses accuracy, thus resulting in deterioration of a distortion characteristic. A standard value of a distortion characteristic is determined for each apparatus using a switching circuit. A switching circuit is required to increase a maximum signal amplitude that the switching circuit can handle, while a value of a distortion characteristic is suppressed at the standard value or less.

In general, the maximum signal amplitude (VRFmax) that a switching circuit including n FETs connected in series can handle is determined based on a control voltage value Vc, the number n of stages of FETs connected in series, and a threshold voltage Vth, and can be expressed by Equation 1.
VRFₘₐₓ=2n(Vc+Vth) [Equation 1]
For example, where the control voltage Vc is 3 V and the threshold voltage Vth is −1.0 V in the switching circuit of FIG. 20, the number n of FET stages and thus VRFₘₐₓ becomes 16 V based on Equation 1.

As described above, to increase the maximum signal amplitude VRFₘₐₓ that the switching circuit can handle, the threshold level Vth or the number n of FET stages is increased.

However, when a threshold voltage of a FET is increased to raise the maximum signal amplitude that the switching circuit can handle, an ON resistance of the FET is increased. This causes increase in insertion loss. Moreover, when the number of stages of FETs connected in series is increased, increase in a chip size is caused as well as increase in insertion loss, thus resulting in increase in costs.

### SUMMARY OF THE INVENTION

It is therefore an object of the present invention to solve the above-described problems and to achieve a radio frequency switching circuit which can deal with a high power input without causing increase in insertion loss and a chip size.

To achieve the above-described object, according to the present invention, a radio frequency switching circuit including a basic switching section in which a plurality of field effect transistors (FETs) are connected in series is formed to have a configuration in which two FETs located in both ends of a basic switching section, respectively, are less prone to being turned ON, compared to other FETs.

Specifically, a first radio frequency switching circuit according to the present invention is directed to a radio frequency switching circuit including a plurality of input/output terminals for inputting/outputting a radio frequency signal and a plurality of basic switching sections each being provided between adjacent two of the plurality of input/output terminals and is characterized in that each of the basic switching sections includes three or more field effect transistors connected in series, and each of two of the field effect transistors connected in series which are located in both ends of the basic switching section, respectively, has a higher threshold voltage than respective threshold voltages of other ones of the field effect transistors.

In the first radio frequency switching circuit, even when a high power radio frequency signal is input, the two field effect transistors located in both ends are less prone to being turned ON. Therefore, the maximum signal amplitude that the radio frequency switching circuit can deal with can be increased. On the other hand, a threshold voltage of each of the field effect transistors located between the two field effect transistors is lower than the threshold voltages of the two field effect transistors. Thus, increase in insertion loss in an entire basic switching section can be suppressed. As a result, a radio frequency switching circuit having a large maximum input power and exhibiting an excellent radio frequency distortion characteristic can be achieved.

A second radio frequency switching circuit according to the present invention is directed to a radio frequency switching circuit including a plurality of input/output terminals for inputting/outputting a radio frequency signal and a plurality of basic switching sections each being provided between adjacent two of the plurality of input/output terminals and is characterized in that each said basic switching section includes three or more field effect transistors connected in series, and each of two of the field effect transistors connected in series which are located in both ends of each said basic switching section, respectively, has a larger gate width than respective gate widths of other ones of the field effect transistors.

In the second radio frequency switching circuit, a floating capacitance between the gate and the source or between the gate and the drain is larger in the two field effect transistors located in both ends than in other field effect transistors. Accordingly, in the two field effect transistors located in both ends, a radio frequency voltage applied between the gate and the source or between the gate and the drain in an OFF state is lower, compared to other field effect transistors. Therefore, even when a high power radio frequency signal is input, the two field effect transistors located in both ends are less prone to being turned ON. As a result, the maximum signal amplitude that the radio frequency switching circuit can deal with can be increased. On the other hand, only respective gate widths of the field effect transistors located in both ends are increased and therefore increase in chip area in an entire basic switching section can be suppressed.

A third radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section includes three or more field effect transistors connected in series, and each of two of the field effect transistors connected in series which are located in both ends of each said basic switching section, respectively, has a different gate length from respective gate lengths of other ones of the field effect transistors.

In the third radio frequency switching circuit, a floating capacitance between the gate and the source, between the gate and the drain or between the source and the drain is larger in the two field effect transistors located in both ends than in other field effect transistors. Accordingly, in the two field effect transistors located in both ends, a radio frequency voltage applied between the gate and the source or between the gate and the drain in an OFF state is lower, compared to other field effect transistors. Therefore, even when a high power radio frequency signal is input, the two field effect transistors located in both ends are less prone to being turned ON. As a result, the maximum signal amplitude that the radio frequency switching circuit can deal with can be increased. On the other hand, only respective gate lengths of the field effect transistors located in both ends are increased and therefore increase in chip area in an entire basic switching section can be suppressed.

A fourth radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section includes two or more field effect transistors connected in series, at least one of the field effect transistors is a multi-gate field effect transistor in which two or more gates are provided between a source and a drain, and each of ones of a plurality of gates provided in the field effect transistors including the multi-gate field effect transistor connected in series which are located in both ends of each said basic switching section, respectively, has a higher threshold voltage than respective threshold voltages of other ones of the plurality of gates.

In the fourth radio frequency switching circuits, even when a high power radio frequency signal is input, the gates located in both ends are less prone to being turned ON. Therefore, the maximum signal amplitude that the radio frequency switching circuit can deal with can be increased. Moreover, only respective threshold voltages of the gates located in both ends are increased and therefore increase in insertion loss in an entire basic switching section can be suppressed. Furthermore, with use of at least one multi-gate transistor, increase in chip area can be suppressed.

A fifth radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section includes two or more field effect transistors connected in series, at least one of the field effect transistors is a multi-gate field effect transistor in which two or more gates are provided between a source and a drain, and each of ones of a plurality of gates provided in the field effect transistors including the multi-gate field effect transistor connected in series which are located in both ends of each said basic switching section, respectively, has a larger gate width than respective gate widths of other ones of the plurality of gates.

In the fifth radio frequency switching circuit, a radio frequency voltage applied to the gates located in both ends of an OFF state is lower, compared to other gates. Accordingly, even when a high power radio frequency signal is input, the gates located in both sides are less prone to being turned ON. As a result, the maximum signal amplitude that the radio frequency switching circuit can deal with can be increased. Moreover, with use of at least one multi-gate transistor, increase in chip area can be suppressed.

A sixth radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section includes two or more field effect transistors connected in series, at least one of the field effect transistors is a multi-gate field effect transistor in which two or more gates are provided between a source and a drain, and each of ones of a plurality of gates provided in the field effect transistors including the multi-gate field effect transistor connected in series which are located in both ends of each said basic switching section, respectively, has a different gate length from respective gate lengths of other ones of the plurality of gates.

In the sixth radio frequency switching circuit, a radio frequency voltage applied to the gates located in both ends of an OFF state is lower, compared to other gates. Accordingly, even when a high power radio frequency signal is input, the gates located in both sides are less prone to being turned ON. As a result, the maximum signal amplitude that the radio frequency switching circuit can deal with can be increased. Moreover, with use of at least one multi-gate transistor, increase in chip area can be suppressed.

A seventh radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section is a multi-gate field effect transistor in which three or more gates are provided between a drain and a source, and each of two of the gates located closest to the source and the drain, respectively, has a higher threshold voltage than respective threshold voltages of other ones of the gates.

In the seventh radio frequency switching circuit, increase in insertion loss in an entire basic switching section can be suppressed. Furthermore, each of the basic switching sections is formed of a single multi-gate field effect transistor, and thus increase in chip area can be suppressed.

An eighth radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section is a multi-gate field effect transistor in which three or more gates are provided between a drain and a source, and each of two of the gates located closest to the source and the drain, respectively, has a larger gate width than respective gate widths of other ones of the gates.

In the eighth radio frequency switching circuit, a radio frequency voltage applied to the gates located in both ends of an OFF state is lower, compared to other gates. Accordingly, even when a high power radio frequency signal is input, the gates located in both sides are less prone to being turned ON. As a result, the maximum signal amplitude that the radio frequency switching circuit can deal with can be increased. Moreover, each of the basic switching sections is formed of a single multi-gate field effect transistor, and thus increase in chip area can be suppressed.

A ninth radio frequency switching circuit according to the present invention is directed to a radio frequency switching circuit including a plurality of input/output terminals for inputting/outputting a radio frequency signal and a plurality of basic switching sections each being provided between adjacent two of the plurality of the input/output terminals and is characterized in that each said basic switching section is a multi-gate field effect transistor in which three or more gates are provided between a drain and a source, and each of two of the gates located closest to the source and the drain, respectively, has a different gate length from respective gate lengths of other ones of the gates.

In the ninth radio frequency switching circuit, a radio frequency voltage applied to the gates located in both ends of an OFF state is lower, compared to other gates. Accordingly, even when a high power radio frequency signal is input, the gates located in both sides are less prone to being turned ON. As a result, the maximum signal amplitude that the radio frequency switching circuit can deal with can be increased. Moreover, each of the basic switching sections is formed of a single multi-gate field effect transistor, and thus increase in chip area can be suppressed.

It is preferable that each one of the radio frequency switching circuits of the present invention further includes a basic switching section provided between at least one of the plurality of input/output terminals and a ground. With this configuration, at least one input/output terminal can be grounded with respect to a radio frequency signal. Therefore, conduction between input/output terminals can be more reliably cut off.

Moreover, in such a case, basic switching sections having different configurations may be used for a basic switching section provided between input/output terminals and a basic switching section provided between an input/output switching section and a ground, respectively. For example, it is preferable that in any one of the first through ninth radio frequency switching circuits of the present invention, a basic switching section having the same configuration as that of the basic switching sections of any one of the first through ninth radio frequency switching circuits is further provided between at least one of the input/output terminals and a ground.

A semiconductor device according to the present invention is characterized by including any one of the radio frequency switching circuits of the present invention integrated on a semiconductor substrate.

In the semiconductor device of the present invention, a radio frequency switching circuit having a small insertion loss and a small chip size and exhibiting an excellent distortion characteristic is integrated on a substrate. Thus, a semiconductor device which can deal with high power and is compact in size can be achieved.

In a radio frequency switching circuit according to the present invention and a semiconductor device using the radio frequency switching circuit, the maximum signal amplitude that the radio frequency switching circuit can deal with can be increased without causing increase in insertion loss and chip size. Therefore, a radio frequency switching circuit or a semiconductor device exhibiting an excellent distortion characteristic even when high power is input can be achieved.

### BRIEF DESCRIPTION OF THE DRAWINGS

FIG. 1 is a circuit diagram of a radio frequency switching circuit according to the first embodiment of the present invention.

FIG. 2 is a plan view illustrating a semiconductor substrate on which the circuit of the first embodiment of the present invention is integrated.

FIGS. 3A, 3B, 3C and 3D are cross-sectional views, taken along the lines IIIa-IIIa, IIIb-IIIb, IIIc-IIIc, and IIId-IIId of FIG. 2, respectively, of the semiconductor substrate on which the radio frequency switching circuit of the first embodiment of the present invention is integrated.

FIG. 4 is a graph showing the relationship between input power and harmonic distortion for the radio frequency switching circuit of the first embodiment of the present invention.

FIG. 5 is a circuit diagram of a radio frequency switching circuit according to a second embodiment of the present invention.

FIG. 6 is a plan view illustrating a semiconductor substrate on which the radio frequency switching circuit of the second embodiment of the present invention is integrated.

FIG. 7 is a circuit diagram of a radio frequency switching circuit according to a third embodiment of the present invention.

FIG. 8 is a plan view illustrating a semiconductor substrate on which the radio frequency switching circuit of the third embodiment of the present invention is integrated.

FIGS. 9A, 9B, 9C and 9D are cross-sectional views, taken along the lines IXa-IXa, IXb-IXb, IXc-IXc, and IXd-IXd of FIG. 8, respectively, of the semiconductor substrate on which the radio frequency switching circuit of the third embodiment of the present invention is integrated.

FIG. 10 is a circuit diagram of a radio frequency switching circuit according to a fourth embodiment of the present invention.

FIG. 11 is a plan view illustrating a semiconductor substrate on which the radio frequency switching circuit of the fourth embodiment of the present invention is integrated.

FIGS. 12A, 12B, 12C and 12D are cross-sectional views, taken along the lines XIIa-XIIa, XIIb-XIIb, XIIc-XIIc, and XIId-XIId of FIG. 11, respectively, of the semiconductor substrate on which the radio frequency switching circuit of the fourth embodiment of the present invention is integrated.

FIG. 13 is a circuit diagram of a radio frequency switching circuit according to a fifth embodiment of the present invention.

FIG. 14 is a plan view illustrating a semiconductor substrate on which the radio frequency switching circuit of the fifth embodiment of the present invention is integrated.

FIGS. 15A and 15B are cross-sectional views, taken along the lines XVa-XVa and XVb-XVb of FIG. 14, respectively, of the semiconductor substrate on which the radio frequency switching circuit of the fifth embodiment of the present invention is integrated.

FIG. 16 is a circuit diagram of a radio frequency switching circuit according to a sixth embodiment of the present invention.

FIG. 17 is a plan view illustrating a semiconductor substrate on which the radio frequency switching circuit of the sixth embodiment of the present invention is integrated.

FIG. 18 is a cross-sectional view, taken along the line XVIII-XVIII of FIG. 17, of the semiconductor substrate on which the radio frequency switching circuit of the sixth embodiment of the present invention is integrated.

FIG. 19 is a circuit diagram illustrating a radio frequency switching circuit according to a seventh embodiment of the present invention.

FIG. 20 is a circuit diagram illustrating a radio frequency switching circuit according to a known example.

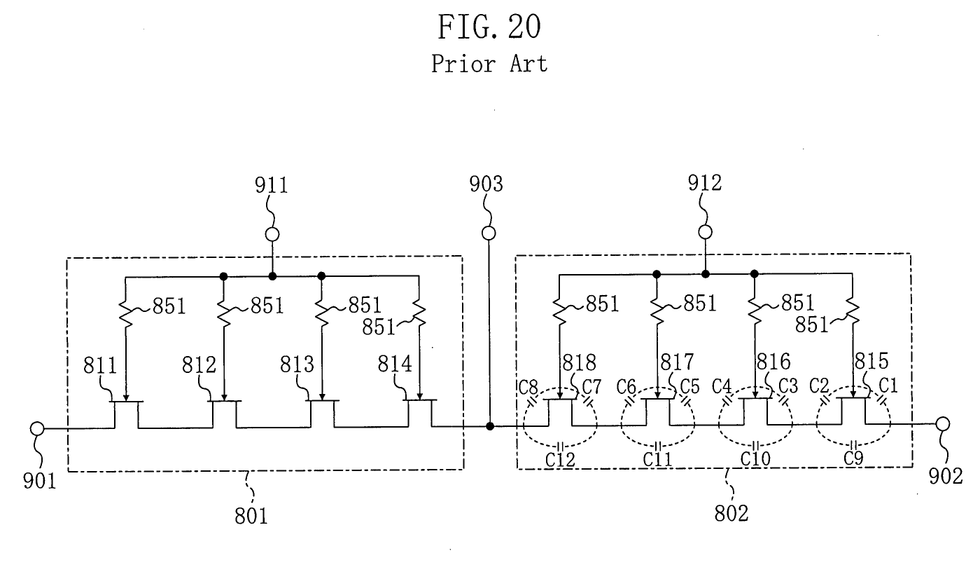

### DESCRIPTION OF THE PREFERRED EMBODIMENTS

### First Embodiment

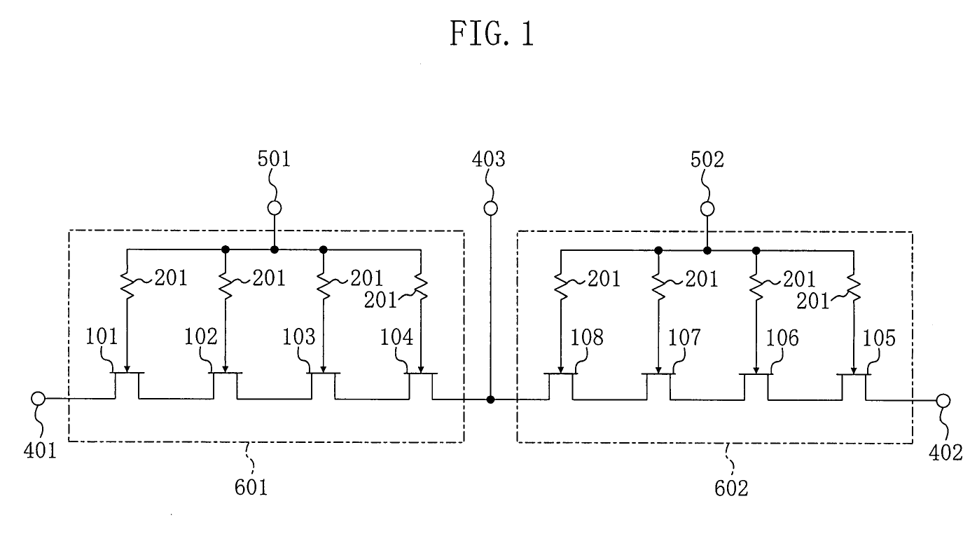

A first embodiment of the present invention will be described with reference to FIGS. 1, 2, 3 and 4. FIG. 1 is a diagram of an equivalent circuit of a radio frequency switching circuit according to the first embodiment of the present invention. As shown in FIG. 1, a single-pole/double-throw (referred to as SPDT) including three input/output terminals, i.e., a first input/output terminal 401, a second input/output terminal 402 and a third input/output terminal 403, and two basic switching sections, i.e., a first basic switching section 601 and a second basic switching section 602 is formed. The first basic switching section 601 and the second basic switching section 602 are provided between the first input/output terminal 401 and the third input/output terminal 403 and between the third input/output terminal 403 and the second input/output terminal 402, respectively.

The first basic switching section 601 includes four depletion type FETs, i.e., a first FET 101, a second FET 102, a third FET 103 and a fourth FET 104 which are connected in series between the first input/output terminal 401 and the third input/output terminal 403. A drain and a source of the first FET 101, a drain and a source of the second FET 102, a drain and a source of the third FET 103 and a drain and a source of the fourth FET 104 are connected in series in this order. The source of the first FET 101 is connected to the first input/output terminal 401. The drain of the fourth FET 104 is connected to the third input/output terminal 401. Each of respective gates of the first through fourth FETs 101 through 104 are connected to a control terminal 501 via a resistance 201.

The second basic switching section 602 has a similar configuration to that of the first basic switching section 601. In the second basic switching section 601, a drain and a source of a fifth FET 105, a drain and a source of a sixth FET 106, a drain and a source of a seventh FET 107 and a drain and a source of an eighth FET 108 are connected in series in this order. The source of the fifth FET 105 is connected to the second input/output terminal 402. The drain of the eighth FET 108 is connected to the input/output terminal 403. Moreover, each of respective gates of the fifth through eighth FETs 105 through 108 is connected to a control terminal 502 via a resistance 201.

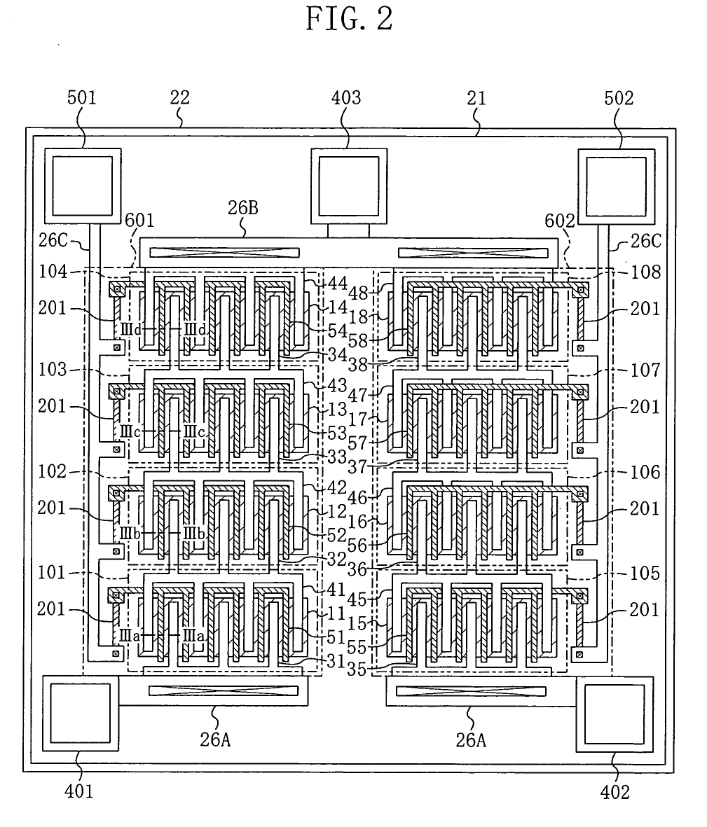

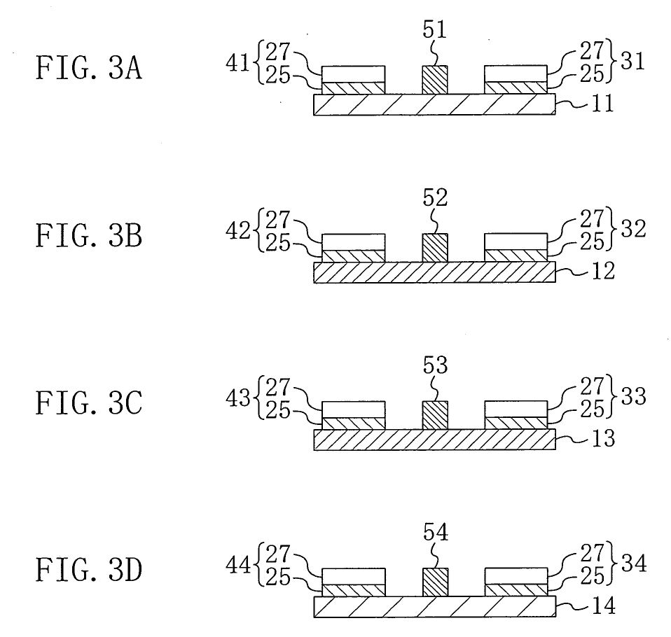

Hereinafter, a configuration of an actual radio frequency switching circuit will be described further in detail with reference to FIGS. 2 and 3. FIG. 2 is a plan view illustrating a planar structure of a semiconductor substrate on which the circuit of FIG. 1 is integrated. FIGS. 3A, 3B, 3C and 3D are cross-sectional views of the semiconductor substrate taken along the lines IIIa-IIIa, IIIb-IIIb, IIIc-IIIc, and IIId-IIId of FIG. 2, respectively.

As shown in FIG. 2 and FIGS. 3A through 3D, a first input/output terminal 401, a second input/output terminal 402, a third input/output terminal 403, a first control terminal 501 and a second control terminal 502 are formed on a surface of a region 21 of a semiconductor substrate 22 covered with a dielectric material.

First, second, third and fourth FETs 101, 102, 103 and 104 are formed on part of the semiconductor substrate 22 located between the first input/output terminal 401 and the third input/output terminal 403.

The first FET 101 includes an active layer 11 formed on the surface of the semiconductor substrate 22 and a source 31, a drain 41 and a gate 51 which are formed on the active layer 11. As shown in FIG. 3A, each of the source 31 and the drain 41 is formed of a cap layer 25 provided on the active layer 11 and an electrode 27 provided on the cap layer 25. The drain 41 has a comb-like structure having four tooth-like projecting portions disposed in a lateral direction at regular intervals so that each of the tooth-like projecting portions extends in a perpendicular direction to the lateral direction on the active layer 11. Moreover, the source 31 has a comb-like structure having three tooth-like projecting portions disposed so as to face the drain 41 and be located in interspaces between the tooth-like projecting portions of the drain 41, respectively. The gate 51 also has a comb-like structure having six tooth-like projecting portions formed so that each of the tooth-like projecting portions is located in an interspace between the one of the three tooth-like projecting portions of the source 31 and an associated one of the four tooth-like projecting portions of the drain 41.

In the same manner, the second FET 102, the third FET 103 and the fourth FET 104 are formed on a second active layer 12, a third active layer 13 and a fourth active layer 14, respectively. The source 31 of the first FET 101 is electrically connected to the first input/output terminal 401 via a metal interconnect 26A, and the drain 44 of the fourth FET 104 is electrically connected to the third input/output terminal 403 via a metal interconnect 26B. Moreover, the drain 41 of the first FET 101 and the source 32 of the second FET 102 are connected to each other, the drain 42 of the FET 102 and the source 33 of the third FET 103 are connected to each other, and the drain 43 of the third FET 103 and the source 34 of the fourth FET 104 are connected each other. Thus, the four FETs are connected in series between the input/output terminal 401 and the third input/output terminal 403.

Moreover, each of the gate 51 of the first FET 101, the gate 52 of the second FET 102, the gate 53 of the third FET 103 and the gate 54 of the fourth FET 104 is connected to the first control terminal 501 via a resistance 201 and a metal interconnect 26C. Thus, a first basic switching section 601 is formed.

Between the second input/output terminal 402 and the third input/output terminal 403, a second basic switching section 602 including fifth, sixth, seventh, and eighth FETs 105, 106, 107 and 108 is formed in the same manner as that for the first basic switching section 601. Thus, as a whole, a radio frequency switching circuit, i.e., a SPDT circuit is integrated on the semiconductor substrate 22.

In this embodiment, each of the six tooth-like projecting portions of the gate 51 in the first FET 101 has part in contact with the first active layer 11 and the length of the part is 100 μm. Thus, the gate width of the first FET 101 is 600 μm. Also, the first through eighth FETs 101 through 108 have the same electrode structure. Therefore, each of the first through eighth FETs 101 through 108 has a gate width of 600 μm.

On the other hand, respective impurity concentrations of the first active layer 11, the fourth active layer 14, the fifth active layer 15 and the eighth active layer 18 on which the first FET 101, the fourth FET 104, the fifth FET 105 and the eighth FET 108 are formed, respectively, are set to be lower than respective impurity concentrations of the second active layer 12, the third active layer 13, the sixth active layer 16 and the seventh active layer 17 on which the second FET 102, the third FET 103, the sixth FET 106, the seventh FET 107 are formed, respectively. The threshold voltage of each of the first FET 101, the fourth FET 104, the fifth FET 105 and the eighth FET 108 is −0.5 V. This is higher than the threshold voltage of each of the second FET 102, the third FET 103, the sixth FET 106 and the seventh FET 107, i.e., −1.0 V.

Next, the operation of the radio frequency switching circuit of this embodiment will be described. When a radio frequency signal input from the input/output terminal 401 is output to the input/output terminal 403, the first basic switching section 601 is in an ON state and the second basic switching section 602 is in an OFF state, i.e., the fifth through eighth FETs 105 through 108 are in an OFF state. Under the above-described condition, when a radio frequency signal is input to the first input/output terminal 401, the radio frequency signal is also applied to the fifth through eighth FETs 105 through 108 and a radio frequency voltage divided by a floating capacitance of each FET is superimposed onto each gate.

Thus, when a radio frequency signal with a nearly maximum signal amplitude is input to the first input/output terminal 401, the sixth FET 106 or the seventh FET 107 with a low threshold voltage first becomes closer to an ON state. However, at the same time, a terminal voltage of an adjacent FET to the sixth FET 106 or the seventh FET 107 increases to compensate the increase in a voltage in the sixth FET 106 or the seventh FET 107, so that an OFF state of the sixth FET 106 or the seventh FET 107 is maintained. When the signal amplitude is further increased, the fifth FET 105 or the eighth FET 108 is turned ON eventually. A maximum signal amplitude that can be dealt with in the radio frequency switching circuit is determined by the threshold voltage of the fifth FET 105 or the eighth FET 108. On the other hand, insertion loss of the second basic switching section 602 can be suppressed at a low level, compared to the case where all of the threshold voltages of the fifth through eighth FETs 105 through 108 are increased.

In the radio frequency switching circuit of this embodiment, the maximum signal amplitude VRFₘₐₓ expressed by Equation 1 is improved by about 4 V, compared to the case where each of respective threshold voltages of FETs is −1.0 V. The improvement of the maximum amplitude VRFₘₐₓ in terms of power is 36.8 dBm and shows that a maximum allowable power is improved by 1.8 dBm, compared to the known example.

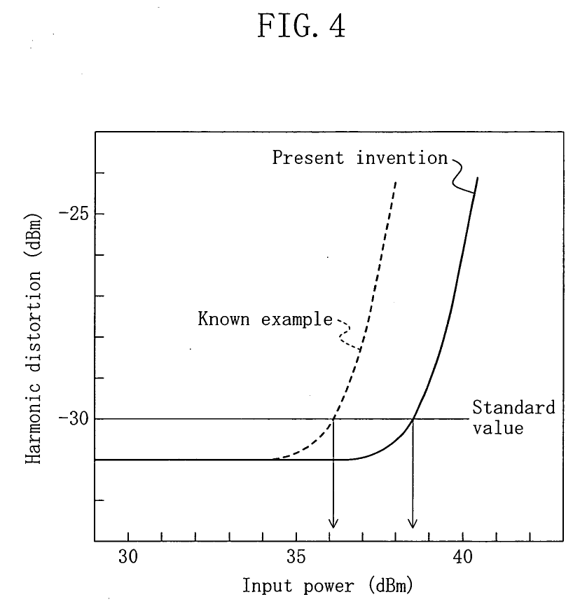

FIG. 4 is a graph showing the relationship between input power and harmonic distortion. In FIG. 4, the abscissa indicates input power value (dBm) and the ordinate indicates harmonic distortion (dBm). As shown in FIG. 4, when the radio frequency switching circuit of this embodiment (indicated by a solid line) is used, an input power value at which −30 dBm, i.e., a standard value for harmonic distortion is achieved is improved by about 2 dBm, compared to the case where the known radio frequency switch (indicated by a dashed line) is used. On the other hand, increase in insertion loss at this time is 0.1 dBm or less, which is negligibly small.

As has been described, the radio frequency switching circuit of this embodiment is so configured that in a basic switch section in which a plurality of FETs are connected in series, threshold voltages of two FETs located in both ends, respectively, are higher than a threshold voltage of a FET located between the two FETs. Thus, a maximum input power can be increased and insertion loss can be suppressed at a low level. As a result, a harmonic distortion characteristic can be improved.

Note that in this embodiment, the threshold voltages of the FETs in both ends are set to be 50% higher than threshold voltages of other FETs. However, by setting the threshold voltage of the FETS in both ends to be 20% or more higher, and preferably 30% or more higher than the threshold voltages of other FETs, the same effects can be achieved. In consideration of increase in insertion loss, the threshold voltage is preferably 0 V or less.

Also, in this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

Moreover, in this embodiment, a basic switching section is so configured to have four FETs connected in series. However, if a basic switching section includes three or more FETs connected in series, the same effect can be achieved.

### Second Embodiment

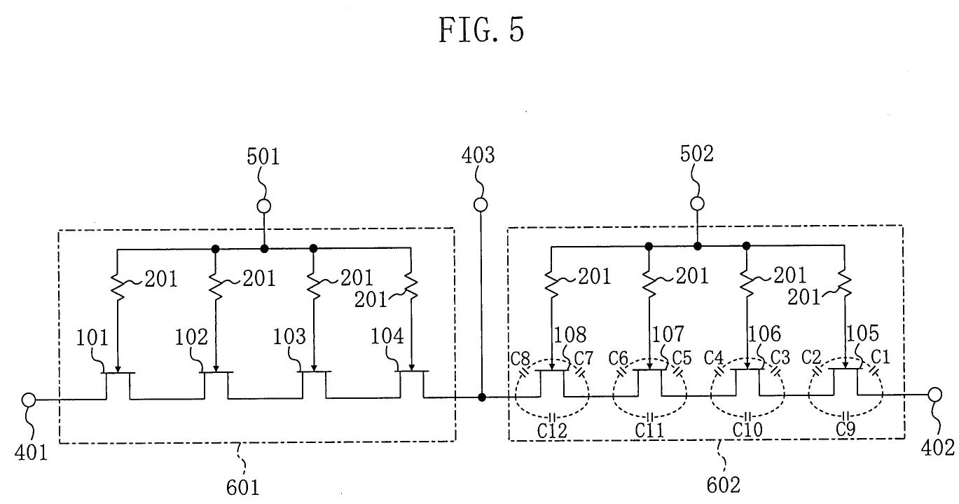

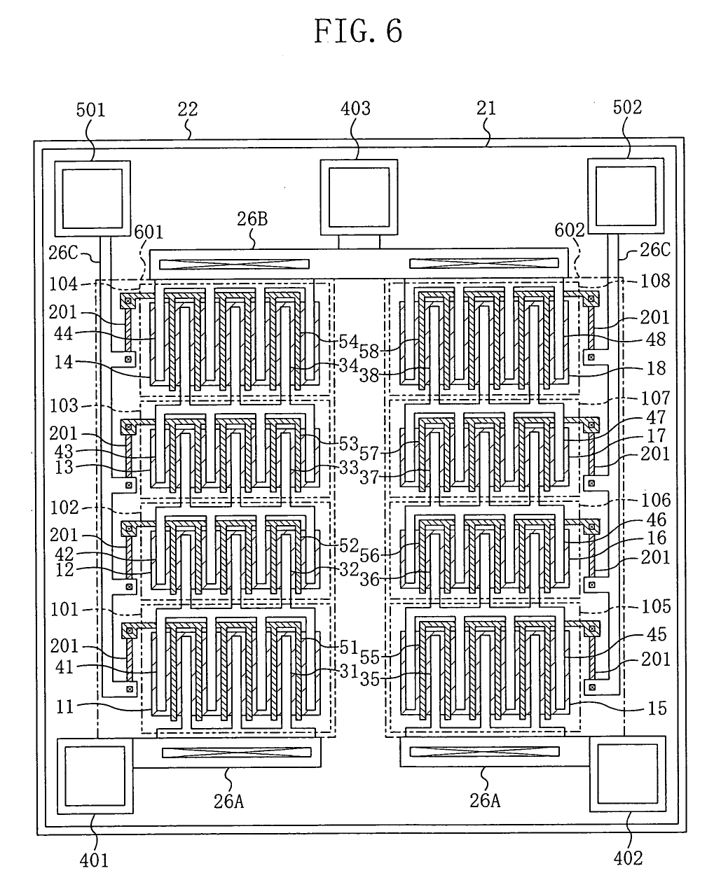

A second embodiment of the present invention will be described with reference to FIGS. 5 and 6. FIG. 5 is a diagram of an equivalent circuit of a radio frequency switching circuit according to the second embodiment of the present invention. As shown in FIG. 5, a SPDT circuit including the first basic switching section 601 and the second basic switching section 602 is formed in the same manner as in the first embodiment.

FIG. 6 is a plan view illustrating how the radio frequency switching circuit of this embodiment is integrated on a semiconductor substrate. In FIG. 6, each member also shown in FIG. 2 is identified by the same reference numeral and therefore the description thereof will be omitted.

In this embodiment, as shown in FIG. 6, the first active layer 11, the fourth active layer 14, the fifth active layer 15 and the eighth active layer 18 are formed on the semiconductor substrate 22 so as to have a larger width in the direction in which respective gates of the active layers extend (in the gate width direction) than those of the second active layer 12, the third active layer 13, the sixth active layer 16 and the seventh active layer 17. Thus, in each of the first FET 101, the fourth FET 104, the fifth FET 105 and the eighth FET 108, each tooth-like projecting portion of a gate extending in a perpendicular direction to the lateral direction on an active layer has a larger length, compared to the second FET 102, the third FET 103, the sixth FET 106 and the seventh FET 107. Accordingly, a gate width of each of the first FET 101, the fourth FET 104, the fifth FET 105 and the eighth FET 108 is larger than that of each of the second FET 102, the third FET 103, the sixth FET 106 and the seventh FET 107.

In this embodiment, the gate width of each of the first FET 101, the fourth FET 104, the fifth FET 105 and the eighth FET 108 is set to be 3 mm and the gate width of each of the second FET 102, the third FET 103, the sixth FET 106 and the seventh FET 107 is set to be 2 mm.

In this embodiment, on the other hand, respective impurity concentrations in the first through eighth active layers 11 through 18 are set to be a certain level. The threshold level of each of the first through eighth FETs 101 through 108 is set to be −1.0 V.

Next, the operation of the radio frequency switching circuit when a radio frequency signal input from the input/output terminal 401 is output to the input/output terminal 403 by turning ON the first basic switching section 601 and turning OFF the second basic switching section 602 will be described.

Floating capacitances C1, C3, C5 and C7 are present between the gate and source of the fifth FET 105, between the gate and source of the sixth FET 106, between the gate and source of the seventh FET 107 and between the gate and source of the eighth FET 108, respectively. The fifth through eighth FETs 105 through 108 are in an OFF state at this time. Floating capacitances C2, C4, C6 and C8 are present between the gate and drain of the fifth FET 105, between the gate and drain of the sixth FET 106, between the gate and drain of the seventh FET 107 and between the gate and drain of the eighth FET 108, respectively. And floating capacitances C9, C10, C11 and C12 are present between the source and drain of the fifth FET 105, between the source and drain of the sixth FET 106, between the source and drain of the seventh FET 107 and between the source and drain of the eighth FET 108, respectively.

In this embodiment, the gate width of each of the fifth FET 105 and the eighth FET 108 is 1.5 times larger than that of each of the sixth FET 106 and the seventh FET 107. Accordingly, a value of each of the floating capacitances C1, C2, C7 and C8 is 1.5 times larger than that of each of the floating capacitances C3, C4, C5 and C6.

On the other hand, the radio frequency signal input from the input/output terminal 401 is applied to each of the fifth through eighth FETs 105 through 108 in an OFF state and a radio frequency voltage divided by a floating capacitance of each FET is superposed on the gate of each of the fifth through eighth FETs 105 through 108.

Thus, in this embodiment, each of respective voltages applied between the gate and source of each of the fifth FET 105 and the eighth FET 108 and between the gate and drain of each of the fifth FET 105 and the eighth FET 108 corresponds to one tenth of an amplitude of a signal that has been input thereto and thus can be reduced to four fifth of a voltage applied when all of the floating capacitances C1 through C8 are the same. Accordingly, with the configuration of this embodiment, the maximum signal amplitude that the radio frequency switching circuit can handle can be improved to a level 1.25 times higher than that in the known example. For example, when the control voltage is 3 V, the maximum signal amplitude that the known radio frequency switching circuit can handle in which respective gate widths of all FETs are the same is 16.0 V. In contrast, the maximum signal amplitude that the radio frequency switching circuit of this embodiment can handle is 22.3 V. Moreover, by increasing the gate width of each of the fifth FET 105 and the eighth FET 108, insertion loss can be advantageously reduced.

On the other hand, only the gate widths of the fifth FET 105 and the eighth FET 108 are increased. Thus, a chip area is increased only by about 10%, compared to the known example. Therefore, increase in chip size and resulting increase in costs can be suppressed.

In this embodiment, each of the respective gate widths of FETs located in both ends, respectively, is increased to be 1.5 times larger than the gate widths of other FETs. However, as long as each of the respective gate widths of the FETs in both ends is increased to be 1.2 or more times larger, preferably 1.3 or more times larger than the gate widths of other FETs, the same effects can be achieved. In consideration of the chip size and the like, each of the gate widths of the FETs in both ends is preferably 6 mm or less.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

### Third Embodiment

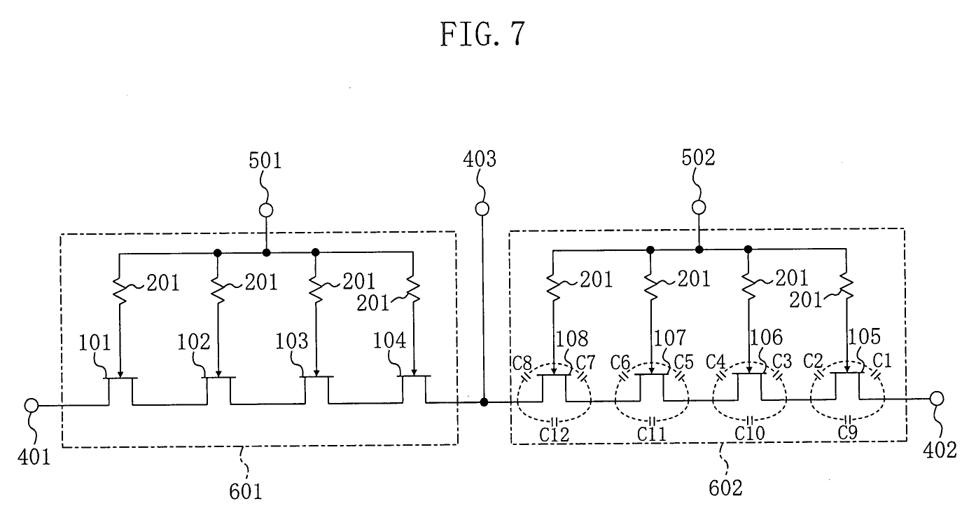

A third embodiment of the present invention will be described with reference to FIGS. 7, 8 and 9. FIG. 7 is a diagram of an equivalent circuit of a radio frequency switching circuit according to the third embodiment of the present invention. As shown in FIG. 7, a SPDT circuit including the first basic switching section 601 and the second basic switching section 602 is formed in the same manner as in the first embodiment.

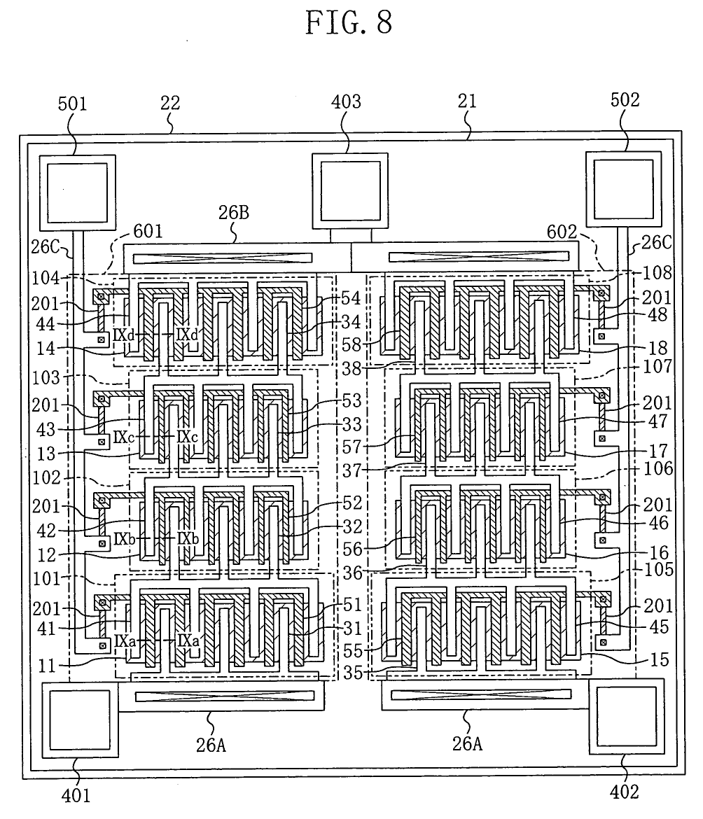

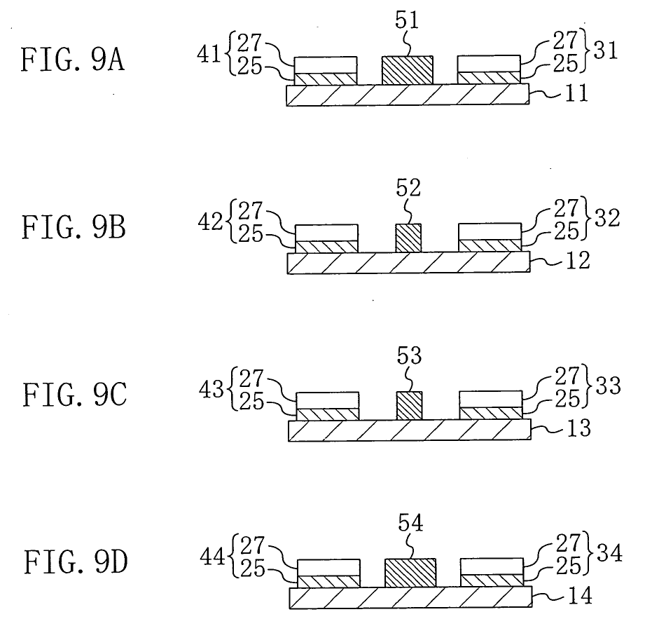

FIG. 8 is a plan view illustrating a planar structure of a semiconductor substrate on which the radio frequency switching circuit of this embodiment is integrated. FIGS. 9A, 9B, 9C and 9D are cross-sectional views of the semiconductor substrate taken along the lines IXa-IXa, IXb-IXb, IXc-IXc, and IXd-IXd of FIG. 8, respectively. Note that in FIG. 8, each member also shown in FIG. 2 is identified by the same reference numeral and therefore the description thereof will be omitted.

In this embodiment, as shown in FIG. 8, the first active layer 11, the fourth active layer 14, the fifth active layer 15 and the eighth active layer 18 are formed on the semiconductor substrate 22 so as to have a larger width in the perpendicular direction to the direction in which respective gates on the active layers extend (in the gate length direction) than those of the second active layer 12, the third active layer 13, the sixth active layer 16 and the seventh active layer 17.

Also, the width of each of tooth-like projecting portions of the gate 51, the gate 54, the gate 55 and the gate 58 is larger than that of each of tooth-like projecting portions of the gate 52, the gate 53, the gate 56 and the gate 57. Each of respective gate lengths of the first FET 101, the fourth FET 104, the fifth FET 105 and the eighth FET 108 is set to be 1.0 μm. Each of respective gate lengths of the second FET 102, the third FET 103, the sixth FET 106 and the seventh FET 107 is set to be 0.5 μm. In this embodiment, on the other hand, respective impurity concentrations in the first through eighth active layers 11 through 18 are set to be a certain level. The threshold level of each of the first through eighth FETs 101 through 108 is set to be −1.0 V.

Next, the operation of the radio frequency switching circuit when a radio frequency signal input from the input/output terminal 401 is output to the input/output terminal 403 by turning ON the first basic switching section 601 and turning OFF the second basic switching section 602 will be described.

Floating capacitances C1, C3, C5 and C7 are present between the gate and source of the fifth FET 105, between the gate and source of the sixth FET 106, between the gate and source of the seventh FET 107 and between the gate and source of the eighth FET 108, respectively. The fifth through eighth FETs 105 through 108 are in an OFF state at this time. Floating capacitances C2, C4, C6 and C8 are present between the gate and drain of the fifth FET 105, between the gate and drain of the sixth FET 106, between the gate and drain of the seventh FET 107 and between the gate and drain of the eighth FET 108, respectively. And floating capacitances C9, C10, C11 and C12 are present between the source and drain of the fifth FET 105, between the source and drain of the sixth FET 106, between the source and drain of the seventh FET 107 and between the source and drain of the eighth FET 108, respectively.

In this embodiment, each of the respective gate lengths of the fifth FET 105 and the eighth FET 108 is larger than those of the sixth FET 106 and the seventh FET 107. Accordingly, a value of each of the floating capacitances C1, C2, C7 and C8 is larger than that of each of the floating capacitances C3, C4, C5 and C6.

On the other hand, the radio frequency signal input from the input/output terminal 401 is applied to each of the fifth through eighth FETs 105 through 108 in an OFF state and a radio frequency voltage divided by a floating capacitance of each FET is superposed onto the gate of each of the fifth through eighth FETs 105 through 108.

Thus, in this embodiment, each of respective voltages applied between the gate and source of each of the fifth FET 105 and the eighth FET 108 and between the gate and drain of each of the fifth FET 105 and the eighth FET 108 is lower than each of respective voltages applied between the gate and source of each of the sixth FET 106 and the seventh FET 107 and between the gate and drain of each of the sixth FET 106 and the seventh FET 107. Accordingly, the maximum signal amplitude that the radio frequency switching circuit can handle can be increased, compared to the known device. Moreover, by increasing the gate length of each of the fifth FET 105 and the eighth FET 108, insertion loss can be advantageously reduced.

On the other hand, only the gate lengths of the fifth FET 105 and the eighth FET 108 are increased. Thus, a chip area is increased only by about 5%, compared to the known example. Therefore, increase in chip size and resulting increase in costs can be suppressed.

In this embodiment, each of the respective gate lengths of FETs located in both ends, respectively, is set to be 0.5 μm. However, as long as each of the respective gate lengths of the FETs in both ends is increased to be 1.2 or more times larger, preferably 1.3 or more times larger than the gate lengths of other FETs, the same effects can be achieved. In consideration of the chip size and the like, the gate length of each of FETs is preferably 2 mm or less.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

### Fourth Embodiment

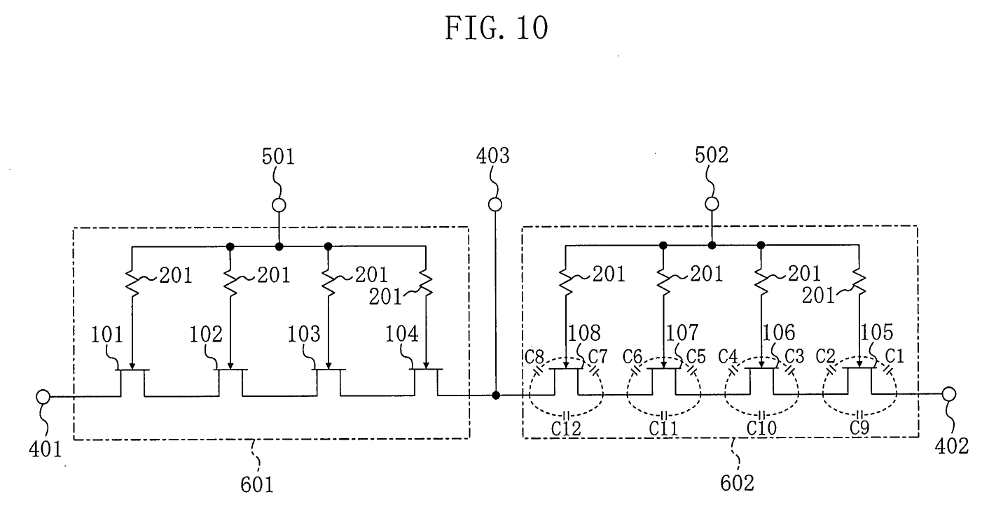

A fourth embodiment of the present invention will be described with reference to FIGS. 10, 11 and 12. FIG. 10 is a diagram of an equivalent circuit of a radio frequency switching circuit according to the fourth embodiment of the present invention. As shown in FIG. 10, a SPDT circuit including the first basic switching section 601 and the second basic switching section 602 is formed in the same manner as in the first embodiment.

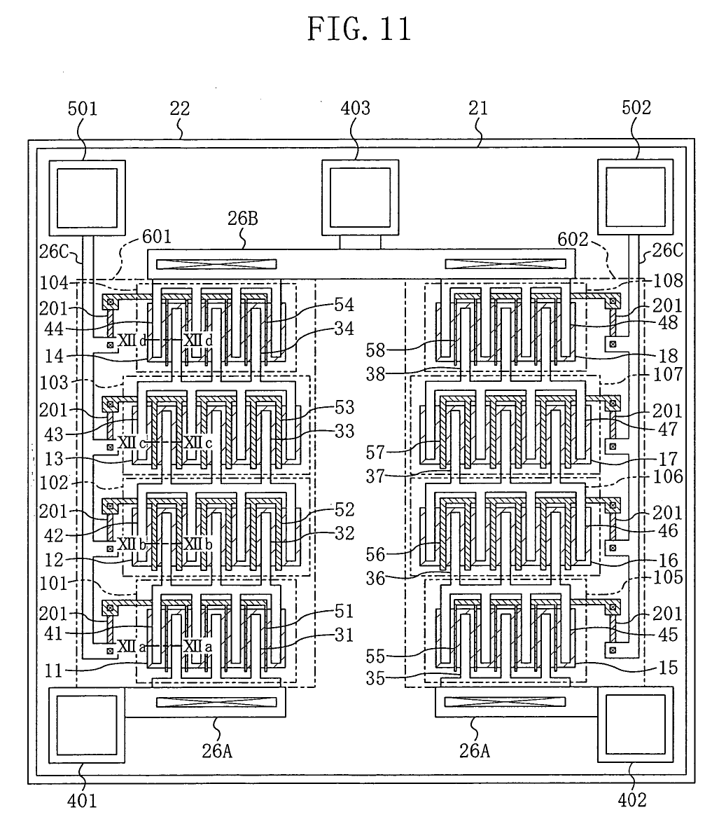

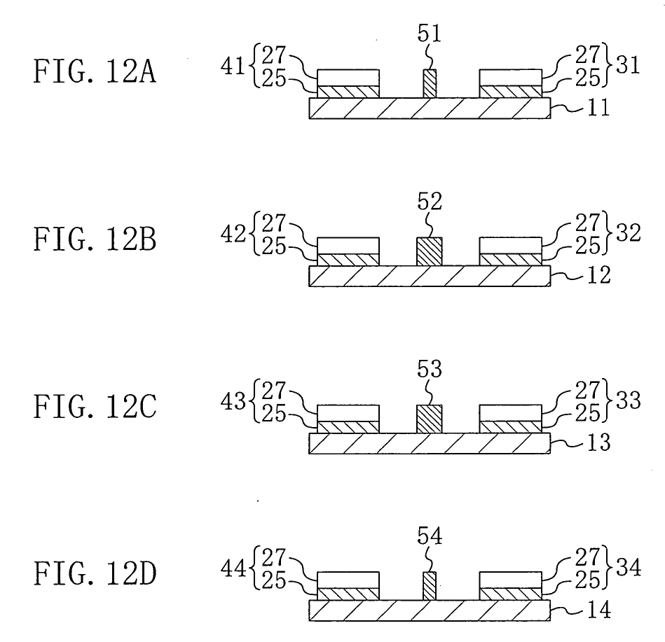

FIG. 11 is a plan view illustrating a planar structure of a semiconductor substrate on which the radio frequency switching circuit of this embodiment is integrated. FIGS. 12A, 12B, 12C and 12D are cross-sectional views of the semiconductor substrate taken along the lines XIIa-XIIa, XIIb-XIIb, XIIc-XIIc, and XIId-XIId of FIG. 11, respectively. Note that in FIG. 11, each member also shown in FIG. 2 is identified by the same reference numeral and therefore the description thereof will be omitted.

In this embodiment, as shown in FIG. 11, the first active layer 11, the fourth active layer 14, the fifth active layer 15 and the eighth active layer 18 are formed on the semiconductor substrate 22 so as to have a smaller width in the gate length direction than those of the second active layer 12, the third active layer 13, the sixth active layer 16 and the seventh active layer 17.

Also, the width of each of tooth-like projecting portions of the gate 51, the gate 54, the gate 55 and the gate 58 is smaller than that of each of tooth-like projecting portions of the gate 52, the gate 53, the gate 56 and the gate 57. Each of respective gate lengths of the first FET 101, the fourth FET 104, the fifth FET 105 and the eighth FET 108 is set to be 0.2 μm. Each of respective gate lengths of the second FET 102, the third FET 103, the sixth FET 106 and the seventh FET 107 is set to be 0.5 μm. In this embodiment, on the other hand, respective impurity concentrations in the first through eighth active layers 11 through 18 are set to be a certain level. The threshold level of each of the first through eighth FETs 101 through 108 is set to be −1.0 V.

Next, the operation of the radio frequency switching circuit when a radio frequency signal input from the input/output terminal 401 is output to the input/output terminal 403 by turning ON the first basic switching section 601 and turning OFF the second basic switching section 602 will be described.

Floating capacitances C1, C3, C5 and C7 are present between the gate and source of the fifth FET 105, between the gate and source of the sixth FET 106, between the gate and source of the seventh FET 107 and between the gate and source of the eighth FET 108, respectively. Floating capacitances C2, C4, C6 and C8 are present between the gate and drain of the fifth FET 105, between the gate and drain of the sixth FET 106, between the gate and drain of the seventh FET 107 and between the gate and drain of the eighth FET 108, respectively. And floating capacitances C9, C10, C11 and C12 are present between the source and drain of the fifth FET 105, between the source and drain of the sixth FET 106, between the source and drain of the seventh FET 107 and between the source and drain of the eighth FET 108, respectively.

In this embodiment, each of the respective gate lengths of the fifth FET 105 and the eighth FET 108 is smaller than that of each of the sixth FET 106 and the seventh FET 107. Accordingly, a value of each of the floating capacitances C9 and C12 is larger than that of each of the floating capacitances C10 and C11.

On the other hand, the radio frequency signal input from the input/output terminal 401 is applied to each of the fifth through eighth FETs 105 through 108 in an OFF state and a voltage corresponding to the sum of a radio frequency voltage divided by a floating capacitance of each FET and a control voltage is applied between the source and drain of each of the fifth through eighth FETs 105 through 108.

Thus, in this embodiment, a voltage applied between the drain and source of each of the fifth FET 105 and the eighth FET 108 is lower than a voltage applied between the drain and source of each of the sixth FET 106 and the seventh FET 107. Accordingly, the maximum signal amplitude that the radio frequency switching circuit can handle can be increased, compared to the known device.

On the other hand, the gate lengths of the fifth FET 105 and the eighth FET 108 are reduced. Thus, a chip area is not increased, compared to the known example. Therefore, increase in chip size and resulting increase in costs can be suppressed.

In this embodiment, each of the respective gate lengths of the FETs located in both ends, respectively, is set to be 0.2 μm and the gate lengths of other FETs are set to be 0.5 μm. However, as long as each of the respective gate lengths of the FETs in both ends is set to be 80% or less, preferably 70% or less of the gate length of the other FETs, the same effects can be achieved. In consideration of efficiency in the process step of forming a gate, the gate length of each of FETs is preferably 0.1 mm or more.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

### Fifth Embodiment

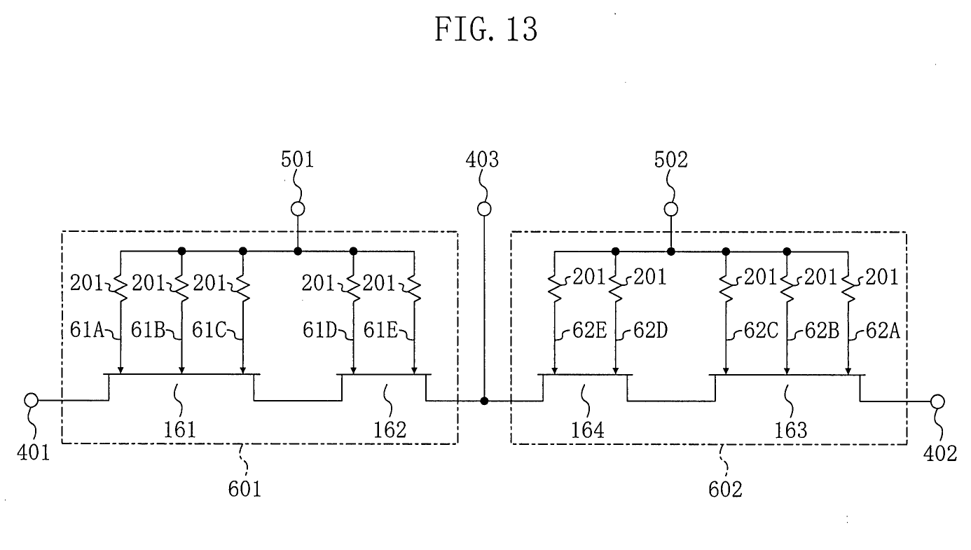

A fifth embodiment of the present invention will be described with reference to FIGS. 13, 14 and 15. FIG. 13 is a diagram of an equivalent circuit of a radio frequency switching circuit according to the fifth embodiment of the present invention. As shown in FIG. 13, a SPDT circuit including three input/output terminals, i.e., the first input/output terminal 401, the second input/output terminal 402 and the third input/output terminal 403 and two basic switching sections, i.e., the first basic switching section 601 and the second basic switching section 602 provided between the first input/output terminal 401 and the third input/output terminal 403 and between the third input/output terminal 403 and the second input/output terminal 402, respectively, is formed.

In the first basic switching section 601, two multi-gate FETs, each including a plurality of gates between a drain and a source, are connected in series between the first input/output terminal 401 and the third input/output terminal 403. A source of the first multi-gate FET 161 is connected to the first input/output terminal 401. A drain of the first multi-gate FET 161 is connected to a source of the second multi-gate FET 162. And a drain of the second multi-gate FET 162 is connected to the third input/output terminal 403.

The first multi-gate FET 161 is a triple-gate FET including a first gate 61A, a second gate 61B and a third gate 61C provided in this order from the source side. The second multi-gate FET 162 is a double-gate FET including a first gate 61D and a second gate 61E.

Each of the first, second and third gates 61A, 61B and 61C of the first multi-gate FET 161 and the first and second gates 61D and 61E of the second multi-gate FET 102 is connected to a control terminal 501 via a resistance 201.

As described above, in the basic switching section 601, five gates, i.e., the first gate 61A, the second gate 61B and the third gate 61C of the first multi-gate FET 161 and the first gate 61D and the second gate 61E of the second multi-gate FET 162 are provided in this order from the first input/output terminal 401 side.

The second basic switching section 602 has a similar configuration to that of the first basic switching section 601. In the second basic switching section 602, a drain and a source of the a third FET 163, i.e., a triple-gate FET and a drain and a source of the fourth FET 164, i.e., a double-gate FET are connected in series in this order. The source of the third FET 163 is connected to the second input/output terminal 402. The drain of the fourth FET 164 is connected to the third input/output terminal 403. Moreover, each of the respective gates of the third FET 163 and the fourth FET 164 is connected to a control terminal 502 via a resistance 201.

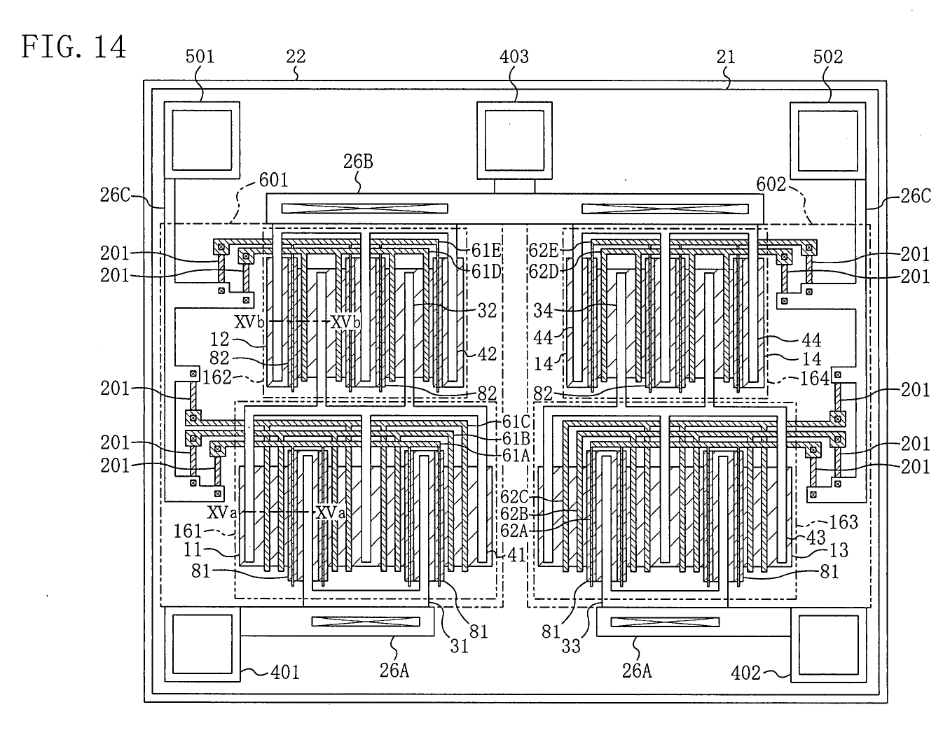

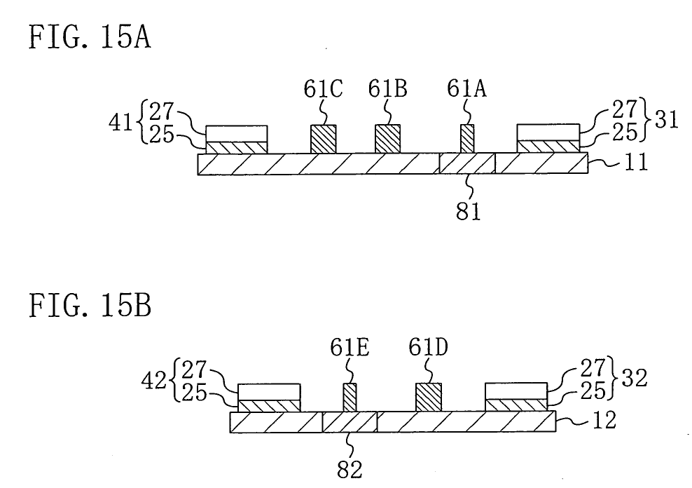

FIG. 14 is a plan view illustrating a planar structure of a semiconductor substrate on which the radio frequency switching circuit of this embodiment is integrated. FIGS. 15A and 15B are cross-sectional views of the semiconductor substrate taken along the lines XVa-XVa and XVb-XVb of FIG. 14, respectively.

As shown in FIG. 14, the first input/output terminal 401, the second input/output terminal 402, the third input/output terminal 403, the first control terminal 501 and the second control terminal 502 are formed on a surface of a region 21 of the semiconductor substrate 22 covered with a dielectric material.

On part of the semiconductor substrate 22 located between the first input/output terminal 401 and the third input/output terminal 403, the first multi-gate FET 161 and the second multi-gate FET 162 are provided in this order from the input/output terminal 401 side.

The first multi-gate FET 161 includes the active layer 11 formed on the surface of the second substrate 22, and the source 31, the drain 41, the first gate 61A, the second gate 61B and the third gate 61C which are formed on the active layer 11. As shown in FIG. 15A, each of the source 31 and the drain 41 is formed of a cap layer 25 provided on the active layer 11 and an electrode 27 provided on the cap layer 25. The drain 41 has a comb-like structure having three tooth-like projecting portions disposed at regular intervals in the lateral direction so that each of the tooth-like projecting portions extends in a perpendicular direction to the lateral direction on the active layer 11. Moreover, the source 31 has a comb-like structure having two tooth-like projecting portions disposed so as to face the drain 41 and be located in interspaces between the three tooth-like projecting portions of the drain 41, respectively. Each of the first, second and third gates 61A, 61B and 61C also has a comb-like structure having four tooth-like projecting portions formed so that each of the tooth-like projecting portions is located in an interspace between one of the two tooth-like projecting portions of the source 31 and an associated one of the three tooth-like projecting portions of the drain 41.

Moreover, the second multi-gate FET 162, i.e., a double gate FET including the source 32, the drain 42, the first gate 61D and the second gate 61E is formed on the second active layer 12.

The source electrode 31 of the first multi-gate FET 161 is connected to the first input/output terminal 401 via a metal interconnect 26A. The drain 42 of the second multi-gate FET 162 is connected to the third input/output terminal 403 via a metal interconnect 26B. The drain electrode 41 of the first multi-gate FET 161 and the source 32 of the second multi-gate FET 162 are connected to each other. Thus, two multi-gate FETs are connected in series between the first input/output terminal 401 and the third input/output terminal 403.

Each of the first gate 61A, the second gate 61B and the third gate 61C of the first multi-gate FET 161 and the first gate 61D and the second gate 61E of the second multi-gate FET 162 is connected to the first control terminal 501 via a resistance 201 and a metal interconnect 26C. Thus, the first basic switching section 601 is formed.

In the first basic switching section 601, respective regions 81 and 82 of the active layers 11 and 12 located under the first gate 61A of the first multi-gate FET 161 and the second gate 61E of the second multi-gate FET 162, respectively, which are located in both ends of the first basic switching section 601 has a larger dimension in the gate width direction than those of other regions. Accordingly, each of the gate 61A and the gate 61E in both ends of the first basic switching section 601 is formed so as to have a larger gate width than those of other gates. Each of the respective gate widths of the first gate 61A of the first multi-gate FET 161 and the second gate 61E of the second multi-gate FET 162 is 4 mm. Each of the respective gate widths of the second and third gates 61B and 61C of the first multi-gate FET 161 and the first gate 61D of the second multi-gate FET 162 is 3 mm.

Moreover, each of the respective widths of tooth-like projecting portions of the gate 61A and the gate 61E located in both ends of the first basic switching section 601, respectively, is smaller than that of each of tooth-like projecting portions of other gates. Accordingly, each of the respective gate lengths of the gate 61A of the first multi-gate FET 161 and the second gate 61E of the second multi-gate FET 162 is 0.2 μm. That is, each of the gate lengths of the gate 61A and the gate 61E is set to be smaller than 0.5 μm, i.e., the gate length of each of the second gate 61B and the third gate 61C of the first multi-gate FET 161 and the first gate 61D of the second multi-gate FET 162.

Furthermore, respective regions 81 and 82 of the active layers 11 and 12 located under the gate 61A and the gate 61E which are located in both ends of a first basic switching section 601, respectively, are made to have a low impurity concentration, compared to other regions. Each of the respective threshold voltages of the first gate 61A of the first multi-gate FET 161 and the second gate 61E of the second multi-gate FET 162 is −0.5 V. That is, each of the threshold voltages of the first gate 61A and the second gate 61E is set to be higher than −1.0 V, i.e., the threshold voltage of each of the second gate 61B and the third gate 61C of the first multi-gate FET 161 and the first gate 61D of the second multi-gate FET 162.

A second basic switching section 602 formed of the third FET 163 and the fourth FET 164 is formed between the second input/output terminal 402 and the third input/output terminal 403 in the same manner as the first basic switching section 601. Thus, as a whole, a radio frequency switching circuit, i.e., a SPDT circuit is integrated on the semiconductor substrate 22.

Next, using, as an example, the case where a radio frequency signal input from the input/output terminal 401 is output to the input/output terminal 403 by turning ON the first basic switching section 601 and turning OFF the second basic switching section 602, the operation of the radio frequency switching circuit will be described.

In the radio frequency switching circuit of this embodiment, each of the first gate 62A of the third multi-gate FET 163 and the second gate 62E of the fourth multi-gate FET 164 located in both ends of the second basic switching section, respectively, has a higher threshold voltage, a larger gate width, and a smaller gate length than those of each of the second gate 62B and the third gate 62C of the third multi-gate FET 163 and the first gate 62D of the fourth multi-gate FET 164.

Accordingly, the first gate 62A of the third multi-gate FET 163 and the second gate 62E of the fourth multi-gate FET 164 are less prone to being turned ON, compared to the second gate 62B and the third gate 62C of the third multi-gate FET 163 and the first gate 62D of the fourth multi-gate FET 164.

Moreover, a radio frequency voltage applied to the first gate 62A of the third multi-gate FET 163 and the second gate 62E of the fourth multi-gate FET 164 is smaller than a voltage applied to the second gate 62B and the third gate 62C of the third multi-gate FET 163 and the first gate 62D of the fourth multi-gate FET 164.

Accordingly, the maximum input signal amplitude that the radio frequency switching circuit of this embodiment can handle becomes larger, compared to the case where all of the gates of the third multi-gate FET 163 and the fourth multi-gate FET 164 have the same threshold, the same gate width and the same gate length.

On the other hand, by using multi-gate FETs, a footprint on the semiconductor substrate can be reduced, compared to the case where a configuration in which a plurality of single-gate FETs are connected in series and the gate lengths and the gate widths of FETs are set to be the same as those described above is formed. Therefore, the size of the radio frequency switching circuit can be reduced.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

In this embodiment, the respective gate lengths of the first gate 61A of the first multi-gate FET, the second gate 61E of the second multi-gate FET, the first gate 62A of the third multi-gate FET and the second gate 62E of the fourth multi-gate FET are set to be smaller than those of other gates. Even when the gate lengths of the first gate 61A, the second gate 61E, the first gate 62A and the second gate 62E are set to be larger than those of other FETs, the same effects can be achieved.

Moreover, in this embodiment, two multi-gate FETs are connected in series. However, two or more multi-gate FETs may be connected in series and also a multi-gate FET and a single gate FET may be connected in series.

### Sixth Embodiment

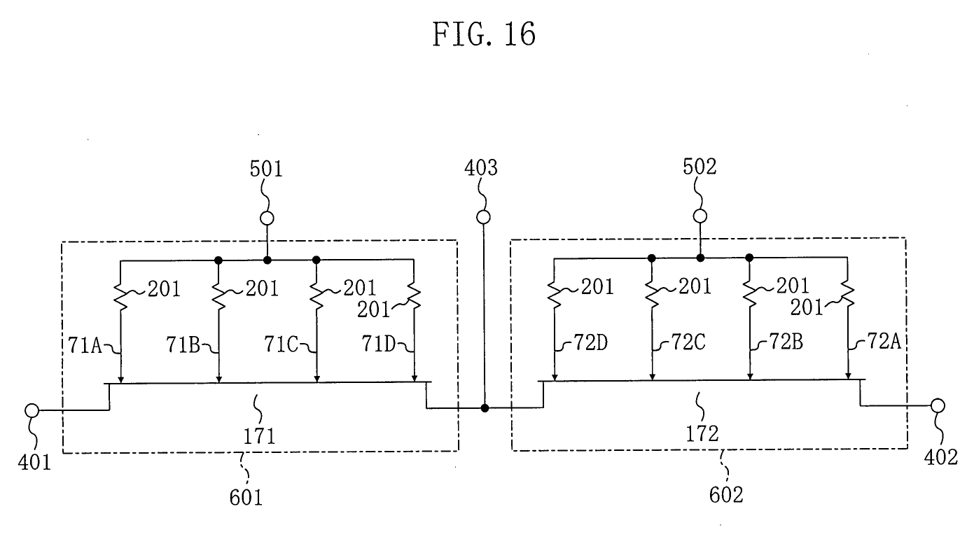

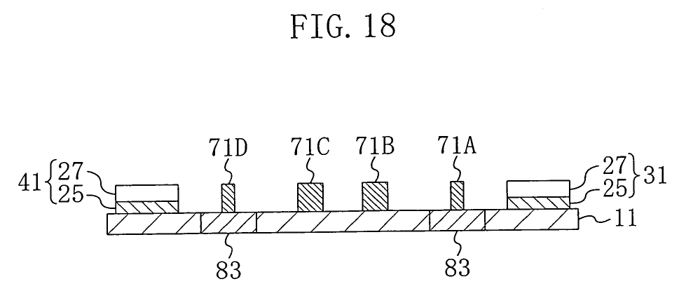

A sixth embodiment of the present invention will be described with reference to FIGS. 16 and 18. FIG. 16 is a diagram of an equivalent circuit of a radio frequency switching circuit according to the sixth embodiment of the present invention. As shown in FIG. 16, a SPDT circuit including three input/output terminals, i.e., a first input/output terminal 401, a second input/output terminal 402 and a third input/output terminal 403 and two basic switching sections, i.e., a first basic switching section 601 and a second basic switching section 602 provided between a first input/output terminal 401 and a third input/output terminal 403 and between a third input/output terminal 403 and a second input/output terminal 402, respectively, is formed.

The first basic switching section 601 is formed of a quad-gate FET including four gates provided between a drain and a source. A source electrode 31 of a first quad-gate FET 171 is connected to the first input/output terminal 401 and a drain electrode 41 of the first quad-gate FET 171 is connected to the third input/output terminal 403.

Between the source electrode 31 and the drain electrode 41, a first gate 71A, a second gate 71B, a third gate 71C and the fourth gate 71D are formed in this order from the source side. Each of the first, second, third and fourth gates 71A, 71B, 71C and 71D is connected to the control terminal 501 via a resistance 201.

The second basic switching section 602 has a similar configuration to that of the first basic switching section 601. A source 32 of a second quad-gate FET 172 is connected to the second input/output terminal 402 and a drain 42 of the second quad-gate FET 172 is connected to the third input/output terminal 403.

Between the source 32 and the drain 42, a first gate 72A, a second gate 72B, a third gate 72C, and a fourth gate 72D are formed in this order from the source side. Each of the first, second, third and fourth gates 72A, 72B, 72C and 72D is connected to the control terminal 502 via a resistance 201.

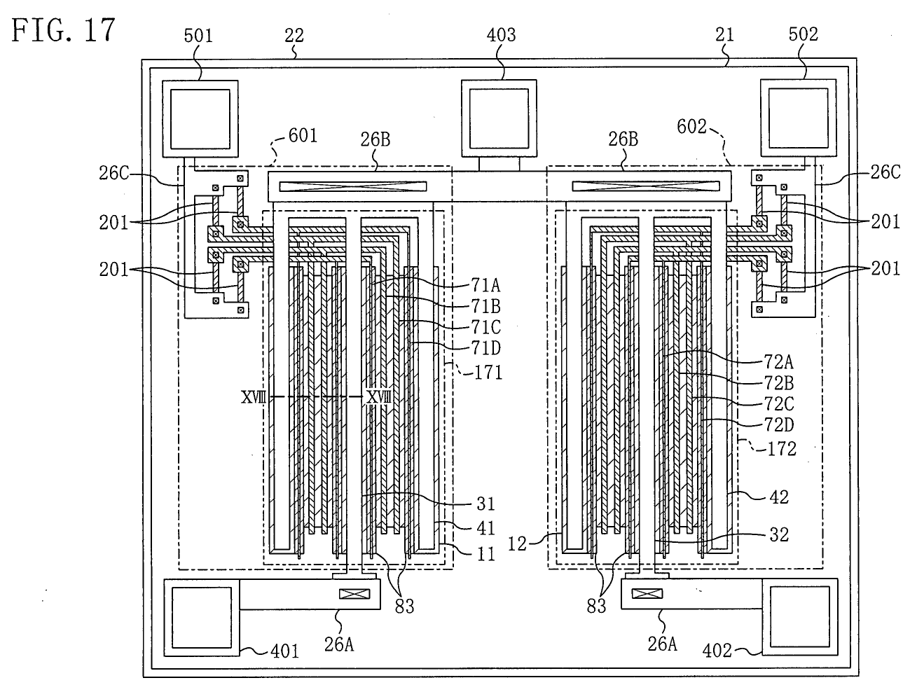

FIG. 17 is a plan view illustrating a planar structure of a semiconductor substrate on which the radio frequency switching circuit of this embodiment is integrated. FIG. 18 is a cross-sectional view of the semiconductor substrate taken along the line XVIII-XVIII of FIG. 17. As shown in FIG. 17, the first input/output terminal 401, the second input/output terminal 402, the third input/output terminal 403, the first control terminal 501 and the second control terminal 502 are formed on a surface of a region 21 of a semiconductor substrate 22 covered by a dielectric material.

On part of the semiconductor substrate 22 located between the first input/output terminal 401 and the third input/output terminal 403, the first quad-gate FET 171 is formed. The first quad-gate FET 171 includes an active layer 11 formed on a surface of the semiconductor substrate 22 and a source 31, a drain 41 and first, second, third, and fourth gates 71A, 71B, 71C and 71D which are formed on the active layer 11. As shown in FIG. 18, each of the source 31 and the drain 41 is formed of a cap layer 25 formed on the active layer 11 and an electrode 27 formed on the cap layer 25.

The drain 41 includes two tooth-like projecting portions provided in both ends of the active layer 11, respectively, so that each of the tooth-like projecting portions extends in a perpendicular direction to the lateral direction on the active layer 11. The source 31 is provided between the two tooth-like projecting portions so as to face the drain 41. Moreover, each of the first, second, third and fourth gates 71A, 71B, 71C and 71D is formed of two tooth-like projecting portions each being formed between the source 31 and one of the two tooth-like projecting portions of the drain 41.

The source 31 of the first quad-gate FET 171 is connected to the first input/output terminal 401 via a metal interconnect 26A. The drain 41 is connected to the third input/output terminal 403 via a metal interconnect 26B.

Each of the first gate 71A, the second gate 71B, the third gate 71C and the fourth gate 71D of the first quad-gate FET 171 is connected to the first control terminal 501 via a resistance 201 and a metal interconnect 26C. Thus, the first basic switching section 601 is formed.

A region 83 of the first active layer 11 located under each of the tooth-like projecting portions of the first gate 71A and the fourth gate 71D of the first quad-gate FET 171 has a larger dimension in the gate width direction, compared to other regions. Each of respective gate widths of the first gate 71A and the fourth gate 71D is 2 mm. That is, each of the first gate 71A and the fourth gate 71D is formed to have a larger gate width than 1.5 mm, i.e., a gate width of each of the second gate 71B and the third gate 71.

Moreover, the width of each of tooth-like projecting portions of the first gate 71A and the fourth gate 71D of the first quad-gate FET 171 is smaller than that of each of tooth-like projecting portions of the second gate 71B and the third gate 71C. Each of respective gate lengths of the first gate 71A and the fourth gate 71D is set to be 0.2 μm. That is, each of the first gate 71A and the fourth gate 71D is formed to have a smaller gate length than 0.5 μm, i.e., a gate length of each of the second gate 71B and the third gate 71C.

Furthermore, the region 83 of the first active layer 11 located under each of the tooth-like projecting portions of the first gate 71A and the fourth gate 71D is made to have a low impurity concentrations, compared to other regions. Each of the respective threshold voltages of the first gate 71A and the fourth gate 71D is −0.5 V. That is, each of the threshold voltages of the first gate 71A and the fourth gate 71D is set to be higher than −1.0 V, i.e., the threshold voltage of each of the second gate 71B and the third gate 71C.

Between the second input/output terminal 402 and the third input/output terminal 403, the second basic switching section 602 formed of the second quad-gate FET 172 is formed so as to have a similar configuration to that of the first basic switching section 601. Thus, as a whole, a radio frequency switching circuit, i.e., a SPDT circuit is integrated on the semiconductor substrate 22.

Next, using, as an example, the case where a radio frequency signal input from the input/output terminal 401 is output to the input/output terminal 403 by turning ON the first basic switching section 601 and turning OFF the second basic switching section 602, the operation of the radio frequency switching circuit will be described.

In the second quad-gate 172 in an OFF state, each of the first gate 72A located closest to the source and the fourth gate 72D located closest to the drain has a higher threshold, a larger gate width and a smaller gate length than those of each of the second gate 72B and the third gate 72C. Thus, the first gate 72A and the fourth gate 72D are less prone to being turned ON, compared to the second gate 72B and the third gate 72C, and a radio frequency voltage applied to the first gate 72A and the fourth gate 72D is lower than a voltage applied to the second gate 72B and the third gate 72C.

Accordingly, the maximum input signal amplitude that the radio frequency switching circuit of this embodiment can handle becomes larger, compared to the case where all of the gates of the quad-gate FETs have the same threshold, the same gate width and the same gate length.

On the other hand, with use of multi-gate FETs, a footprint on the semiconductor substrate can be reduced, compared to the case where a similar configuration is formed using a plurality of single-gate FETs connected in series. Therefore, the size of the radio frequency switching circuit can be reduced.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

In this embodiment, the respective gate lengths of the first gate 71A and the fourth gate 71D of the first quad-gate 171 and the first gate 72A and the fourth gate 72D of the second quad-gate FET 172 are set to be smaller than those of other gates. Even when the gate lengths of the first gate 71A, the fourth gate 71D and the first gate 72A and the fourth gate 72D are set to be larger than those of other FETs, the same effects can be achieved.

In this embodiment, quad-gate FETs, each including four gates, are used as multi-gate FETs. However, as long as multi-gate FETs each including three or more gates are used, the same effects can be achieved.

### Seventh Embodiment

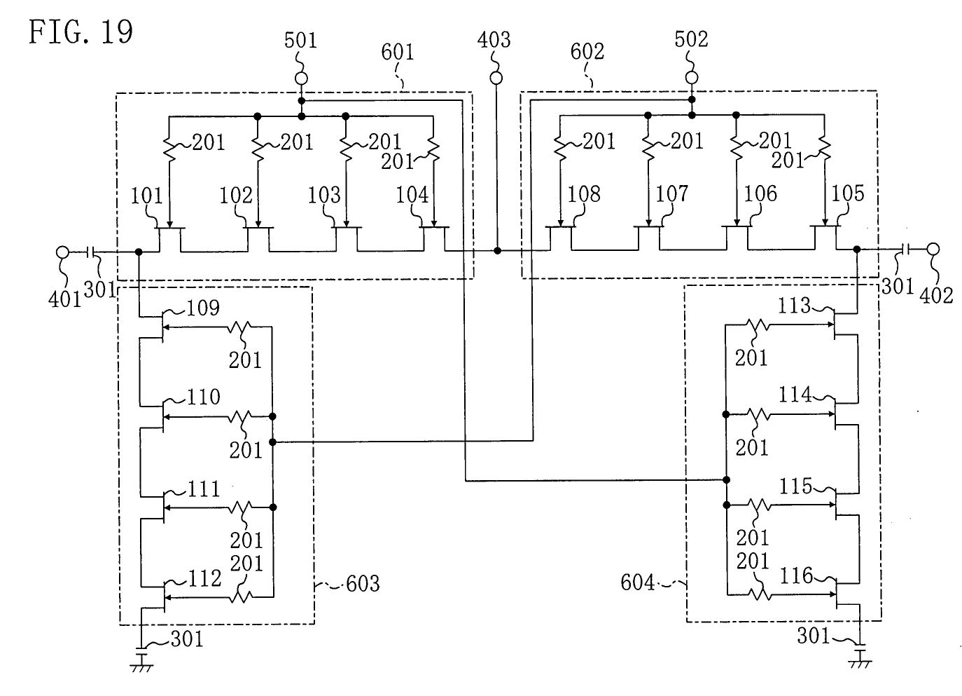

A seventh embodiment of the present invention will be described with reference to FIG. 19. In FIG. 19, each member also shown in FIG. 1 is identified by the same reference numeral and therefore the description thereof will be omitted.

As shown in FIG. 19, in this embodiment, a third basic switching section 603 and a fourth basic switching section 604 are provided as shunts between an input/output terminal 401 and a ground and between an input/output terminal 402 and a ground, respectively. Moreover, each of respective gates of ninth, tenth, eleventh and twelfth FETs 109, 110, 111 and 112 together constituting the third basic switching section 603 is connected to a second control terminal 502 via a resistance 201. Each of respective gates of thirteenth, fourteenth, fifteenth and sixteenth FETs 113, 114, 115 and 116 together constituting the fourth basic switching section 604 is connected to a second control terminal 501 via a resistance 201.

Each of the respective threshold voltages of the first FET 101, the fourth FET 104, the fifth FET 105, the eighth FET 108, the ninth FET 109, the twelfth FET 112, the thirteen FET 113 and the sixteenth FET 116 is set to be −0.5 V and each of respective threshold voltages of other FETs is set to be −1.0 V.

Moreover, in this embodiment, capacitors 301 are inserted between the first and third basic switching sections 601 and 603 and the first input/output terminal 401, between the second and fourth basic switching sections 602 and 604 and the second input/output terminal 402, between the basic switching section 603 and the ground and between the fourth basic switching section 604 and the ground, respectively, so that the whole radio frequency switching circuit is separated from the ground with respect to direct current.

Next, the operation of a radio frequency switching circuit according to this embodiment will be described. When a radio frequency signal is input from the input/output terminal 401 and output from the input/output terminal 403, a voltage of 3 V is applied to the control terminal 501 to turn ON the first, second, third, and fourth FETs 101, 102, 103 and 104 together constituting the first basic switching section 601 and the thirteenth, fourteenth, fifteenth, and sixteenth FETs 113, 114, 115 and 116 together constituting the fourth basic switching section 604 and a voltage of 0 V is applied to the control terminal 502 to turn OFF the fifth, sixth, seventh and eighth FETs 105, 106, 107 and 108 together constituting the second basic switching section 602 and the ninth, tenth, eleventh and twelfth FETs 109, 110, 111 and 112 together constituting the third basic switching section 603.

Thus, conduction between the first input/output terminal 401 and the third input/output terminal 403 with respect to a radio frequency signal is achieved and conduction between the second input/output terminal 402 and the third input/output 403 is cut off with respect to a radio frequency signal. Also, the second input/output terminal 402 is grounded with respect to a radio frequency signal by the fourth basic switching section 604, so that conduction between the second input/output terminal 402 and the third input/output terminal 403 can be more reliably cut off.

In this embodiment, a radio frequency signal input from the input/output terminal 401 is divided to the fifth FET 105, the sixth FET 106, the seventh FET 107 and the eighth FET 108 together constituting the second basic switching section in an OFF state according to floating capacitances and also divided into the ninth FET 109, the tenth FET 110, the eleventh FET 111 and the twelfth FET 12 together constituting the third basic switching section serving as a shunt circuit according to floating capacitances.

Accordingly, the maximum signal amplitude of the radio frequency switch of this embodiment is determined by the respective threshold voltages of the fifth FET 105 and the eighth FET 108 of the second basic switching section 602 and the ninth FET 109 and the twelfth FET 112 of the third basic switching section serving as a shunt circuit. In this embodiment, the respective threshold voltages of the firth FET 105, the eighth FET 108, the ninth FET 109 and the twelfth FET 112 are set to be higher than those of other FETs. Thus, the maximum input amplitude can be increased and also insertion loss can be suppressed at a low level.

In this embodiment, the case where a radio frequency signal input from the input/output terminal 401 is output to the input/output terminal 403 has been described. However, even when a radio frequency signal input from the input/output terminal 402 is output to the input/output terminal 403, the same effects can be achieved.

In this embodiment, the example in which a basic switching section described in the first embodiment is used for each of the first, second, third and fourth basic switching sections 601, 602, 603 and 604 has been described. However, the first through fourth basic switching sections 601 through 604 are not limited thereto, but a basic switching section described in any one of the first through sixth embodiments may be used as each of the switching sections.

Moreover, the example in which the same basic switching section is used for the first basic switching section 601, the second basic switching section 602, and the third basic switching section 603 and the fourth basic switching section 604 serving as shunt circuits has been described. However, different basic switching sections may be used for the first basic switching section 601, the second basic switching section 602, and the third basic switching section 603 and the fourth basic switching section 604 serving as shunt circuits, respectively.

For example, if a basic switching section described in the first embodiment is used for the first basic switching section 601 and the second basic switching section 602 and a basic switching section using a multi-gate FET described in the sixth embodiment is used for the third basic switching section 603 and the fourth basic switching section 604, a radio frequency switching circuit with less distortion and smaller loss can be achieved.

In each of the first through seventh embodiments, a double-pole single-through switching circuit has been described. However, even when a single-pole single-throw switch including only a single basic switching section is used, the same effects can be achieved. Moreover, by combining basic switching sections, a multi-pole multi-throw switch circuit or a multi-pole single-throw switch circuit can be formed.

As has been described, in a radio frequency switching circuit according to the present invention and a semiconductor device using the radio frequency switching circuit, a maximum signal amplitude that the radio frequency switch circuit can handle can be increased without causing increase in insertion loss and chip size. Accordingly, a radio frequency switching circuit and a semiconductor device which exhibit excellent distortion characteristic even when a large power is input can be achieved. Therefore, the radio frequency switching circuit and the semiconductor device of the present invention are useful for a radio frequency switching circuit for performing switching of a radio frequency signal, a semiconductor device using the radio frequency switching circuit and the like.

1. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of the basic switching section, respectively, has a higher threshold voltage than respective threshold voltages of other ones of the field effect transistors.

2. The radio frequency switching circuit of claim 1, further comprising a basic switching section provided between at least one of the plurality of input/output terminals and a ground.

3. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of each said basic switching section, respectively, has a larger gate width than respective gate widths of other ones of the field effect transistors.

4. The radio frequency switching circuit of claim 3, further comprising a basic switching section provided between at least one of the plurality of input/output terminals and a ground.

5. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of each said basic switching section, respectively, has a different gate length from respective gate lengths of other ones of the field effect transistors.

6. The radio frequency switching circuit of claim 5, further comprising a basic switching section provided between at least one of the plurality of input/output terminals and a ground.

7. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a higher threshold voltage than respective threshold voltages of other ones of the plurality of gates.

8. The radio frequency switching circuit of claim 7, further comprising a basic switching section provided between at least one of the plurality of input/output terminals and a ground.

9. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a larger gate width than respective gate widths of other ones of the plurality of gates.

10. The radio frequency switching circuit of claim 9, further comprising a basic switching section provided between at least one of the plurality of input/output terminals and a ground.

11. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a different gate length from respective gate lengths of other ones of the plurality of gates.

12. The radio frequency switching circuit of claim 11, further comprising a basic switching section provided between at least one of the plurality of input/output terminals and a ground.

13. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a higher threshold voltage than respective threshold voltages of other ones of the gates.

14. The radio frequency switching circuit of claim 13, further comprising a basic switching section provided between at least one of the plurality of input/output terminals and a ground.

15. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a larger gate width than respective gate widths of other ones of the gates.

16. The radio frequency switching circuit of claim 15, further comprising a basic switching section provided between at least one of the plurality of input/output terminals and a ground.

17. A radio frequency switching circuit comprising:
a plurality of input/output terminals for inputting/outputting a radio frequency signal; and
a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a different gate length from respective gate lengths of other ones of the gates.

18. The radio frequency switching circuit of claim 17, further comprising a basic switching section provided between at least one of the plurality of input/output terminals and a ground.

19. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of the basic switching section, respectively, has a higher threshold voltage than respective threshold voltages of other ones of the field effect transistors.

20. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of each said basic switching section, respectively, has a larger gate width than respective gate widths of other ones of the field effect transistors.

21. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section includes three or more field effect transistors connected in series, and
wherein each of two of the field effect transistors connected in series which are located in both ends of each said basic switching section, respectively, has a different gate length from respective gate lengths of other ones of the field effect transistors.

22. A semiconductor device comprising:
a semiconductor substrate; and
a radio frequency switching circuit integrated on the semiconductor substrate,
wherein the radio frequency circuit includes a plurality of input/output terminals for inputting/outputting a radio frequency signal and a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a higher threshold voltage than respective threshold voltages of other ones of the plurality of gates.

23. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a larger gate width than respective gate widths of other ones of the plurality of gates.

24. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section includes two or more field effect transistors connected in series,
wherein at least one of the field effect transistors is a multi-gate field effect transistor in which two or more gates are provided between a source and a drain, and
wherein each of ones of a plurality of gates provided in the field effect transistors including the multi-gate field effect transistor connected in series which are located in both ends of each said basic switching section, respectively, has a different gate length from respective gate lengths of other ones of the plurality of gates.

25. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a higher threshold voltage than respective threshold voltages of other ones of the gates.

26. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a larger gate width than respective gate widths of other ones of the gates.

27. A semiconductor device comprising:
a semiconductor substrate; and
a radio frequency switching circuit integrated on the semiconductor substrate,
wherein the radio frequency switching circuit includes a plurality of input/output terminals for inputting/outputting a radio frequency signal and a plurality of basic switching sections each being provided between adjacent two of the plurality of the input/output terminals,
wherein each said basic switching section is a multi-gate field effect transistor in which three or more gates are provided between a drain and a source, and
wherein each of two of the gates located closest to the source and the drain, respectively, has a different gate length from respective gate lengths of other ones of the gates.
